(19) United States
(12) Patent Application Publication
(10) Pub. No.: US 2005/0062137 A1
(43) Pub. Date: Mar. 24, 2005

(54) Vertically-stacked co-planar transmission line structure for IC design

(75) Inventors: Raminderpal Singh, Essex Junction, VT (US); Youri V. Tretiakov, South Burlington, VT (US); Kunal Vaed, Poughkeepsie, NY (US); Wayne H. Woods JR., Essex Junction, VT (US)

Correspondence Address: Steven Fischman;Scully, Scott, Murphy & Presser, 400 Garden City Plaza, Garden City, NY, 11530, US

(73) Assignee: INTERNATIONAL BUSINESS MACHINES CORPORATION, ARMONK, NY (US)

(21) Appl. No.: 10/665,993

(22) Filed: Sep. 18, 2003

(51) Int. Cl. H01L 29/40; H01L 39/00

(52) U.S. Cl. 257/664; 257/662

(57) ABSTRACT

A vertically stacked coplanar transmission line structure for an IC (integrated circuit) is provided which has superior loss and reflection characteristics relative to conventional on-chip transmission line designs. A simple embodiment of the vertically stacked coplanar transmission line structure comprises a micro-strip pair of first and second vertically stacked coplanar conductors, each comprising a metal layer, a next metal layer down, and an intermediate connecting via layer in between the metal layer and the next metal layer down.

### BACKGROUND OF THE INVENTION

1. Field of the Invention

The present invention relates generally to a vertically-stacked co-planar transmission line structure for an IC (integrated circuit) design, and more particularly pertains to on-chip transmission line designs that have superior loss and reflection characteristics relative to conventional on-chip transmission line designs.

2. Discussion of the Prior Art

Conventional on-chip transmission lines are routed in a single metal layer in an IC chip's metal-dielectric stack which result in inferior loss and reflection characteristics.

Stacked conductors have been used in prior art on-chip spiral stacked inductor designs. In these designs, the lower resistance of the stacked conductors results in higher Qs (quality factors) for the spiral inductors.

During operation of prior art on-chip spiral stacked inductors, most of the current flowing in the conductors is located against the inside edges (edges closest to the center of the spiral inductor). Therefore, by increasing the cross sectional area of the conductors at the inside edges of the inductor lines, the resistance in the lines is reduced, thus increasing the Q value achievable by the inductor.

However, the prior art on-chip spiral stacked inductor lines are quite different in implementation and purpose from the stacked coplanar micro-strip/waveguides of the present invention, and are not transmission lines in the sense of being a waveguide interconnect structure having two or more conductors and defining a closed ground return path within the waveguide interconnect structure.

### SUMMARY OF THE INVENTION

Accordingly, the present invention provides a vertically stacked co-planar transmission line structure for an IC design, wherein a transmission line is defined as a waveguide interconnect structure having two or more conductors and defining a closed ground return path within the waveguide interconnect structure.

The transmission line designs of the present invention comprise metal lines in multiple metal and via levels in the metal-dielectric stack of an IC chip. A simple structure metal transmission line comprises a metal layer, the next metal layer down, and the via metal interposed between the two metal layers, all with equal width and length dimensions.

The on-chip stacked coplanar micro-strip/waveguides of the present invention allow chip designers to design a much wider range of characteristic impedances, and also provide dramatic improvements in insertion loss and reflection loss to low-impedance source and load terminations. The structure is designed to be used for long sensitive on-chip interconnects, provides superior performance over conventional one-metal layer structures, and allows custom engineering of the transmission line characteristic impedance.

### BRIEF DESCRIPTION OF THE DRAWINGS

The foregoing objects and advantages of the present invention for a vertically-stacked co-planar transmission line structure for an IC design may be more readily understood by one skilled in the art with reference being had to the following detailed description of several embodiments thereof, taken in conjunction with the accompanying drawings wherein like elements are designated by identical reference numerals throughout the several views, and in which:

FIG. 1 is a vertical cross sectional view of an on-chip coplanar micro-strip structure comprising a pair of first and second coplanar stacked conductors, each comprising a metal layer, the next metal layer down, and a wide via bar in between the two metal layers in the upper metal layers of an RF/BiCMOS technology.

FIG. 2 shows a similar type of on-chip coplanar micro-strip structure comprising a pair of first and second coplanar stacked conductors implemented in a typical base CMOS8SF technology.

FIGS. 3(a) through 3(d) illustrate four different on-chip stacked coplanar transmission line (micro-strip/waveguide) configurations in the base CMOS8SF technology: a) Differential +, − pair; b) Coplanar Signal, Ground micro-strip; c) Ground, Signal, Ground; d) Ground, +, −, Ground.

FIG. 4 illustrates an embodiment which adds an additional via bar and metal layer onto the bottom of the coplanar micro-strip/waveguide in FIG. 1, making the conductor in this type of embodiment three metal layers and two via layers tall.

FIG. 5 illustrates the results of a simulation comparison and illustrates graphs of S-parameter results in the base CMOS8SF technology for an ideal stacked coplanar micro-strip line, a design rule limited stacked coplanar micro-strip line, and a conventional coplanar micro-strip line.

FIG. 6 illustrate the results of a simulation comparison and illustrates graphs of R, L, C, and Z(f) results in CMOS8SF technology for an ideal stacked coplanar micro-strip line, a design rule limited stacked coplanar micro-strip line, and a conventional coplanar micro-strip line.

### DETAILED DESCRIPTION OF THE INVENTION

The present invention provides new on-chip transmission line designs that have superior loss and reflection characteristics relative to conventional on-chip transmission line approaches. In the context of the present invention, a transmission line is defined as a waveguide interconnect structure having two or more conductors and defining a closed ground return path within the waveguide interconnect structure.

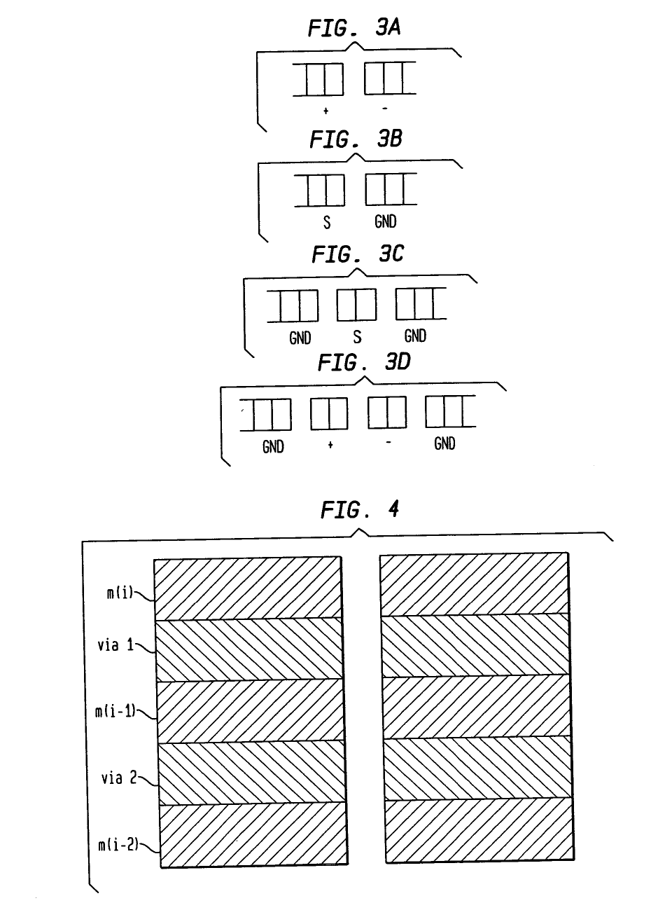

Conventional on-chip transmission lines are routed in a single metal layer in the chip's metal-dielectric stack. In contrast thereto, the transmission line design of the present invention consists of metal lines in multiple metal and via levels in the chip's metal-dielectric stack. The simplest structure is a metal transmission line that is comprised of a metal layer, the next metal layer down, and the via metal in between the two metal layers (all with equal width and length dimensions). This structure can either be a coplanar differential pair of conductors as shown in FIG. 3(a) or a coplanar micro-strip as shown in FIG. 3(b).

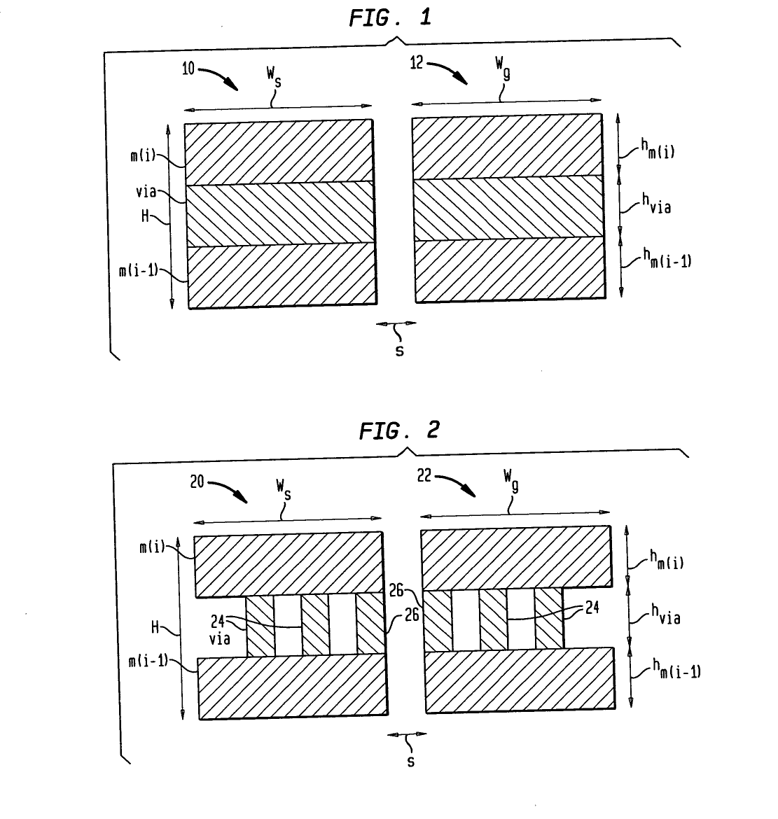

FIGS. 1 and 2 illustrate two exemplary embodiments of coplanar micro-strip lines comprised of first and second coplanar stacked conductors.

FIG. 1 is a vertical cross sectional view of an on-chip coplanar micro-strip structure comprising a pair of first and second coplanar stacked conductors 10, 12, each comprising a metal layer m(i), the next metal layer down m(i-1), and a wide via bar in between the two metal layers in the upper metal layers of an RF/BiCMOS technology. More specifically, each stacked conductor comprises the metal in metal layer m(i), the metal in metal layer m(i-1), and the metal in an intermediate connecting via layer marked via. Each stacked conductor has a height H and a width W (wherein the subscript s stands for signal and the subscript g stands for ground), and the stacked conductors are separated by a distance S. The height of the metal layer m(i) is hm(i), the height of the metal layer m(i-1) is hm(i-1), and the height of the intermediate connecting via layer is hvia.

FIG. 2 shows a similar type of on-chip coplanar micro-strip structure comprising a pair of first and second coplanar stacked conductors 20, 22 implemented in a typical base CMOS8SF technology. Wide via bars over 0.4 μm are not permitted under the base CMOS8SF design rules, so the connecting via metal layer consists of several long parallel via bars 24 spaced 0.4 μm apart. In FIG. 2, three parallel via bars 24 are provided per stacked conductor. Notice that the via bars are placed such that they are as close to the inside edge 26 of the stacked conductor as possible (the edge facing the other line conductor in the micro-strip pair).

FIGS. 3(a) through 3(d) illustrate four different on-chip stacked coplanar transmission line (micro-strip/waveguide) configurations in the base CMOS8SF technology.

FIG. 3(a) illustrates a differential +, − pair transmission line structure wherein the micro-strip pair of first and second vertically stacked coplanar conductors comprise a differential positive and negative pair of transmission line conductors labeled respectively + and −.

FIG. 3(b) illustrates a coplanar signal, ground micro-strip wherein the micro-strip pair of first and second vertically stacked coplanar conductors comprise signal S and ground GND transmission line conductors.

FIG. 3(c) illustrates a ground, signal, ground transmission line structure further comprising a third vertically stacked coplanar conductor wherein the first, second and third vertically stacked coplanar conductors comprise respectively ground GND, signal S and ground GND lines of a waveguide transmission line structure.

FIG. 3(d) illustrates a ground, +, −, ground transmission line structure further comprising third and fourth vertically stacked coplanar conductors, wherein the first, second, third and fourth vertically stacked coplanar conductors comprise respectively a ground GND, a differential positive + and negative − pair of transmission line conductors and a ground of a waveguide transmission line structure.

By using vertical connection vias as long interconnects instead of simple vertical posts, extra thick transmission lines can be implemented. FIGS. 1-3 illustrate coplanar micro-strip/waveguides constructed from two metal layers m(i) and m(i-1) and the via metal between the two metal layers (via). Notice that the total height (thickness) of the coplanar micro-strips in FIGS. 1 and 2, H, is equal to hm(i) + hvia + h(i-1). This provides a greater capacitance per unit length than a coplanar micro-strip line of the same dimensions constructed using only m(i) or m(i-1). In fact, the height advantage is nearly a factor of three improvement in a typical base CMOS8SF metal/dielectric stack. Therefore, the characteristic impedance is lower relative to a coplanar micro-strip line with the same dimensions in either of the two individual metal layers.

By reducing the lowest possible characteristic impedance in on-chip coplanar micro-strips and waveguides, the RF IC designer is given more flexibility and control in designing transmission lines with lower reflective (S₁₁,S₂₂) losses at the source and load line terminations. A major improvement is also possible in the reduction of the magnetic field extension into the lossy silicon substrate by confining EM energy more compactly between the thicker metal line edges of the coplanar micro-strip/waveguide structures depicted in FIGS. 1-2. DC resistance (as well as AC resistance) can be greatly reduced for the structures shown in FIGS. 1-3 over conventional single metal layer coplanar micro-strip/waveguide structures. The lower resistance of these conductors can also be used to combat DC losses in power and ground supply lines in high-density VLSI CMOS as well as reducing charge and discharge times in long high-speed digital lines.

The on-chip stacked coplanar micro-strip/waveguides allow a design of a much wider range of characteristic impedances to chip designers as well as dramatic improvements in insertion loss and reflection loss to low-impedance source and load terminations. The structure is designed to be used for long sensitive on-chip interconnects. It provides superior performance over conventional one-metal layer structures as well as allowing custom engineering of the transmission line characteristic impedance.

In the stacked coplanar micro-strip cross section shown in FIG. 2, the current is concentrated at the edges 26 of the micro-strip conductors that are nearest to the neighboring line. Via bars located at this edge have a similar effect on the line resistance of the long straight coplanar micro-strip as on a prior art on-chip spiral inductor as described above. However, in addition to decreasing resistance, when used in a coplanar micro-strip/waveguide structure, the increase in height H due to metal-via-metal stacking can be used to custom engineer the characteristic impedance of the coplanar micro-strip/waveguide. As mentioned before, the characteristic impedance achievable with the stacked transmission line configurations depicted in FIG. 3 are lower than any similar conventional configurations possible in the present state of the art.

FIG. 4 illustrates an embodiment which adds an additional via bar labeled via 2 and an additional metal layer (mi-2) onto the bottom of the coplanar micro-strip/waveguide in FIG. 1, making the conductor in this type of embodiment three metal layers and two via layers tall. The three metal layers comprise a metal layer m(i), a next metal layer down m(i-1), and a second next metal layer down m(i-2), and a first intermediate connecting via layer labeled via 1 in between the metal layer and the next metal layer down, and a second intermediate connecting via layer labeled via 2 in between the next metal layer and the second next metal layer down.

Similar types of five layer embodiments could be implemented with respect to the embodiments of FIGS. 2 and 3, and additional seven or more layer embodiments could be implemented with respect to the embodiments of FIGS. 1, 2 and 3.

The coplanar micro-strip/waveguide structures shown in FIGS. 1, 2 can be implemented in existing IBM technologies such as BiCMOS7WL and CMOS8SFG. The ideal stacked coplanar micro-strip structure is shown in FIG. 1, where a via bar with the same width as the lines of metal above and below is possible. Unfortunately, lithography and etch bias based design rules do not permit this in most technologies as any misalignment in metal levels will cause increased resistance. In CMOS8SFG, via bars (0.4 um wide) at VQ level need to be at least 0.55 um within above-lying LM line level. In 7WL, via bars (1.24 um wide) at FT level need to be at least 1 um within above-lying E1 line level.

From a fabrication standpoint, analog vias of thickness up to 4 um have been demonstrated in SiGe technologies like 5DM, 7HP, 7WL etc. Precedent exists for the routing of long via bars in the form of the stacked inductors enabled in 7WL and 8SF and the long bar vias routinely used in chip crack-stop guard rings. The maximum length of any allowable VQBAR in CMOS8SFG is 320 um. However, there are examples when this limit is exceeded such as spiral inductors and crack-stop guard rings. In a recent 7HP testsite, via bars for a stacked inductor, with a total running length of 765 um, have been demonstrated with no via RIE process modifications. Conventional metal deposition and planarization processes can be exercised to generate structurally reliable via bars similar to ground-rule square vias.

Another process restriction on such bar vias is that the allowable density in a 63×63 um2 area should not exceed 12%. While designing vertical coplanar micro-strip/waveguide structures, this limitation would have to be addressed since exceeding the via area will cause the resist/ARC to be too thin.

In CMOS8SFG, bar vias are permitted at VQ level only for inductors and as part of the chip-guard. This is primarily to prevent continuous monitoring of non-POR sized vias to check etch/lithography tolerances in a manufacturing technology. Via bars of the size permitted in the stacked inductors can be applied without any modification to the vertical coplanar micro-strip/waveguide structures. The use of longer bar vias (>320 um) into a manufacturable process has also been demonstrated with the results from the recent 7HP testsite.

Electromagnetic modeling of the coplanar micro-strip structures shown in FIG. 1-2 was performed using Ansoft's high-frequency structure simulator (HFSS) 7.0. The lines in the coplanar micro-strip were simulated by assigning even and odd mode ports to the differential line pair. The coplanar micro-strip structures were modeled for both the base CMOS8SF and BiCMOSWL technologies. In the base CMOS 8sf technology, the following dimensions (from FIG. 2) were assigned to the stacked coplanar micro-strip structure: Ws=Wg=5 μm, S=2 μm, H=1.85 μm, hm(i)=0.6 μm, hm(i-1)=0.6 μm. The total micro-strip length was 1 mm, representing a long on-chip interconnect line. The long parallel via bars in between metal layer m(i) and m(i-1) were each 0.4 μm wide and spaced 0.4 μm apart. All metal and via layer heights as well as via widths and spacing were taken from the CMOS8SF design manual. For the simulations, a five metal layer process was assumed in the CMOS8SF technology such that m(i) is the LM metal layer and m(i-1) is the MQ metal layer and the via bar exists in the VQ via layer.

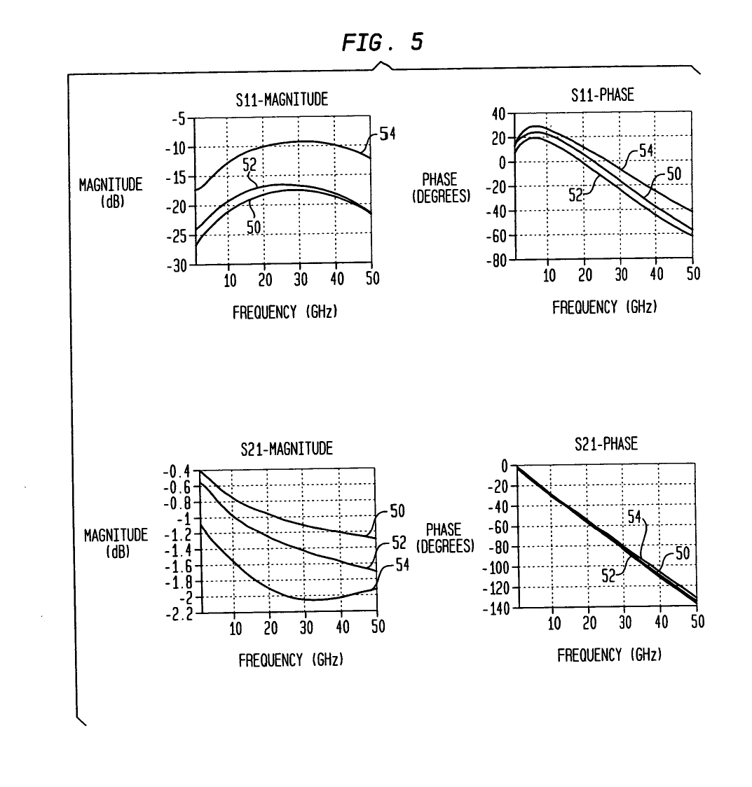

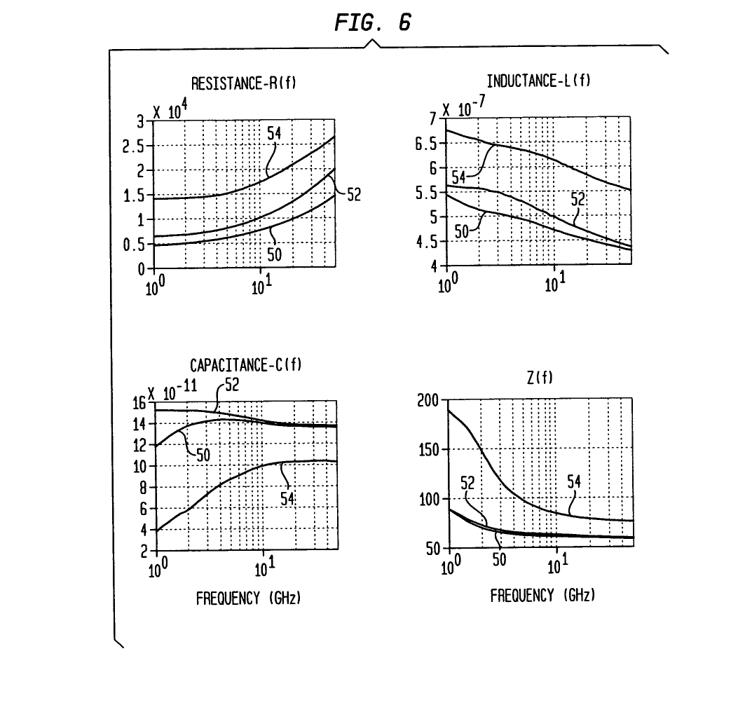

FIGS. 5 and 6 illustrate the results of a simulation in which a stacked coplanar micro-strip structure was compared to a conventional coplanar micro-strip. The conventional micro-strip was assigned exactly the same dimensions, but existed in only the top metal layer (or m(i)/LM).

The traces 50 represent the simulation results for the ideal stacked coplanar micro-strip structure in the five metal layer base CMOS8SF technology. This ideal stacked coplanar micro-strip/waveguide has a via bar whose width is equal to that of the metal lines above and below. The ideal structure cannot be fabricated with the current CMOS8SF process, but represents the performance attainable if the process were dual damascene. The traces 52 are the results for the stacked micro-strip whose cross section is currently possible in the CMOS8SF technology (same as cross section shown in FIG. 2). Finally, the traces 54 are the simulation results for the same size conventional coplanar micro-strip line in only the top metal layer of the five metal layer CMOS8SF technology.

Clearly the new structure represented by the traces 52 has far superior matching to the 50 ω source and load resistances used in the simulation (S₁₁ graph in the top left corner of FIG. 5). This is because the stacked structure, as predicted, has a much lower characteristic impedance than the conventional coplanar micro-strip line (Z(f) graph in the bottom right corner of FIG. 6). In fact, the stacked coplanar micro-strip line shows about a 7 dB improvement in matching at 500 MHz. This equates to a 55% reduction in reflective loss over the conventional coplanar micro-strip line. The total electrical loss produced in the stacked coplanar micro-strip line represented by trace 52 is approximately 0.6 dB less than that of the conventional coplanar micro-strip line at 500 MHz (or a 48% reduction). The resistance of the stacked coplanar micro-strip line (trace 52 in the resistance graph in the upper left corner of FIG. 5 shows a 57% reduction at 500 MHz when compared to the conventional coplanar micro-strip trace 54.

FIG. 5 illustrates the results of the simulation comparison and illustrates graphs of S-parameter results in the base CMOS8SF technology for an ideal stacked coplanar micro-strip line represented by traces 50, a design rule limited stacked coplanar micro-strip line represented by traces 52, and a conventional coplanar micro-strip line represented by traces 54.

FIG. 6 illustrate the results of the simulation comparison and illustrates graphs of R, L, C, and Z(f) results in CMOS8SF technology for an ideal stacked coplanar micro-strip line represented by traces 50, a design rule limited stacked coplanar micro-strip line represented by traces 52, and a conventional coplanar micro-strip line represented by traces 54.

One outstanding benefit to the stacked coplanar micro-strip/waveguide structures of the present invention is the additional range in characteristic impedance made possible by increasing the height of the waveguide conductors. In the characteristic impedance, Z(f), results in the bottom right graph of FIG. 6, the effect of this increase in height can be seen on the characteristic impedance of the stacked differential pair CPW. Note that this change has nothing to do with the decrease in resistance in the line, but is an effect of the change in the coplanar micro-strip's inductance and capacitance. It is clear from the Z(f) graph in the bottom right of FIG. 6 that the stacked coplanar micro-strip line of the present invention is able to achieve dramatically lower characteristic impedances relative to a conventional coplanar micro-strip line. In fact the stacked coplanar micro-strip line shows a 53% reduction in characteristic impedance over the conventional coplanar micro-strip line at 500 MHz.

While several embodiments and variations of the present invention for a vertically-stacked co-planar transmission line structure for an IC design are described in detail herein, it should be apparent that the disclosures and teachings of the present invention will suggest many alternative designs to those skilled in the art.

1. A vertically stacked coplanar transmission line structure for an integrated circuit (IC) chip defining a closed ground return path within the transmission line structure, comprising:
a micro-strip pair of first and second vertically stacked coplanar conductors, each comprising a metal layer, a next metal layer down, and an intermediate connecting via layer in between the metal layer and the next metal layer down.

2. The transmission line structure of claim 1, wherein each vertically stacked coplanar conductor comprises metal in the metal layer m(i), metal in the next metal layer down m(i-1), and metal in the intermediate connecting via layer.

3. The transmission line structure of claim 1, fabricated in upper metal layers of the IC chip.

4. The transmission line structure of claim 1, wherein the intermediate connecting via layer comprises a single via bar which extends across an entire width of the intermediate connecting via layer.

5. The transmission line structure of claim 1, wherein the intermediate connecting via layer comprises a plurality of long parallel via bars spaced apart across a width of the intermediate connecting via layer.

6. The transmission line structure of claim 5, wherein the plurality of long parallel via bars are positioned to be close to an inside edge of the coplanar vertically stacked conductor which faces the other coplanar vertically stacked conductor in the transmission line structure.

7. The transmission line structure of claim 1, wherein the micro-strip pair of first and second vertically stacked coplanar conductors comprise a differential positive and negative pair of transmission line conductors.

8. The transmission line structure of claim 1, wherein the micro-strip pair of first and second vertically stacked coplanar conductors comprise signal and ground transmission line conductors.

9. The transmission line structure of claim 1, further comprising a third vertically stacked coplanar conductor comprising a metal layer, a next metal layer down, and an intermediate connecting via layer in between the metal layer and the next metal layer down, and the first, second and third vertically stacked coplanar conductors comprise respectively ground, signal and ground conductors of a waveguide transmission line structure.

10. The transmission line structure of claim 1, further comprising third and fourth vertically stacked coplanar conductors, each comprising a metal layer, a next metal layer down, and an intermediate connecting via layer in between the metal layer and the next metal layer down, and the first, second, third and fourth vertically stacked coplanar conductors comprise respectively a ground, a differential positive and negative pair of transmission line conductors and a ground of a waveguide transmission line structure.

11. A vertically stacked coplanar transmission line structure for an integrated circuit (IC) chip defining a closed ground return path within the transmission line structure, comprising:
a micro-strip pair of first and second vertically stacked coplanar conductors, each comprising a metal layer, a next metal layer down, a second next metal layer down, a first intermediate connecting via layer in between the metal layer and the next metal layer down, and a second intermediate connecting via layer in between the next metal layer and the second next metal layer down.

12. The transmission line structure of claim 11, wherein each vertically stacked coplanar conductor comprises metal in the metal layer m(i), metal in the next metal layer down m(i-1), metal in the second next metal layer down m(i-2), metal in the first intermediate connecting via layer, and metal in the second intermediate connecting via layer.

13. The transmission line structure of claim 11, fabricated in upper metal layers of the IC chip.

14. The transmission line structure of claim 11, wherein the first intermediate connecting via layer and the second intermediate connecting via layer each comprises a single via bar which extends across an entire width of the intermediate connecting via layer.

15. The transmission line structure of claim 11, wherein the first intermediate connecting via layer and the second intermediate connecting via layer each comprises a plurality of long parallel via bars spaced apart across a width of the intermediate connecting via layer.

16. The transmission line structure of claim 15, wherein the plurality of long parallel via bars are positioned to be close to an inside edge of the coplanar vertically stacked conductor which faces the other coplanar vertically stacked conductor in the transmission line structure.

17. The transmission line structure of claim 11, wherein the micro-strip pair of first and second vertically stacked coplanar conductors comprise a differential positive and negative pair of transmission line conductors.

18. The transmission line structure of claim 11, wherein the micro-strip pair of first and second vertically stacked coplanar conductors comprise signal and ground transmission line conductors.

19. The transmission line structure of claim 11, further comprising a third vertically stacked coplanar conductor comprising a metal layer, a next metal layer down, a second next metal layer down, a first intermediate connecting via layer in between the metal layer and the next metal layer down, and a second intermediate connecting via layer in between the next metal layer and the second next metal layer down, and the first, second and third vertically stacked coplanar conductors comprise respectively ground, signal and ground conductors of a waveguide transmission line structure.

20. The transmission line structure of claim 11, further comprising third and fourth vertically stacked coplanar conductors, each comprising a metal layer, a next metal layer down, a second next metal layer down, a first intermediate connecting via layer in between the metal layer and the next metal layer down, and a second intermediate connecting via layer in between the next metal layer and the second next metal layer down, and the first, second, third and fourth vertically stacked coplanar conductors comprise respectively a ground, a differential positive and negative pair of transmission line conductors and a ground of a waveguide transmission line structure.
